(19) United States
(12) Patent Application Publication
(10) Pub. No.: US 2026/0324319 A1
(43) Pub. Date: Oct. 15, 2026

(54) PLASMA PROCESSING METHOD

(71) Applicant: Hitachi High-Tech Corporation, Minato-ku, Tokyo (JP)

(72) Inventors: Masaya IMAI, Tokyo (JP); Miyako MATSUI, Tokyo (JP); Makoto MIURA, Tokyo (JP); Kenichi KUWAHARA, Tokyo (JP)

(21) Appl. No.: 19/103,688

(22) PCT Filed: Nov. 28, 2023
(86) PCT No.: PCT/JP2023/042604

§ 371 Date: Feb. 13, 2025

(51) Int. Cl. H10P 50/26; H10P 50/00; H10P 50/28

(52) U.S. Cl. CPC H10P 50/267; H10P 50/269; H10P 50/285; H10P 50/71; H10P 50/73

(57) ABSTRACT

A plasma processing method for performing plasma etching, by using a metal wiring pattern, on a metal film formed below the metal wiring pattern includes: a first process of forming a protective film on the metal wiring pattern by plasma generated using a first gas; a second process of etching the metal film by plasma generated using a second gas after the first process; a third process of etching the metal film after the second process by plasma generated using a third gas so that an etching shape of the metal film is a vertical shape after the second process; and a fourth process of removing, by plasma generated using a fourth gas, the protective film formed on the metal wiring pattern. The second process and the third process are repeated until an etching depth of the metal film is a predetermined depth.

### TECHNICAL FIELD

The present invention relates to a plasma processing method.

### BACKGROUND ART

Along with miniaturization and three-dimensional formation of a semiconductor device structure, application of an alternative metal that replaces copper as a wiring metal has been studied. Specific examples thereof include ruthenium that can be patterned by plasma etching. A ruthenium wiring has a stacked-layer structure, and is required to be processed into a pattern by appropriately performing plasma etching via a mask. A ruthenium pattern can be prepared by applying plasma, which is generated from a gas mixture containing an oxygen gas and a halogen gas, to a surface of ruthenium that is masked in advance and etching the surface of ruthenium in a vertical direction. However, with an increase in the number of stacked layers of the wiring and the miniaturization of the wiring in width, it is expected that wiring processing of ruthenium becomes complicated and the number of processes increases.

### CITATION LIST

### Patent Literature

PTL 1: US2022/0139823A

### Non Patent Literature

NPL 1: P. Marien et al., “Integrating 8 nm Self-Aligned Tip-to-Tip to Enable 4-track Standard Cell Architecture as Scaling Booster”, 2023 IEEE International Interconnect Technology Conference (IITC) and IEEE Materials for Advanced Metallization Conference (MAM) (ITC/MAM), Dresden, Germany, 2023, pp. 1-3, DOI: 10.1109/IITC/MAM57687.2023.10154710

### SUMMARY OF INVENTION

### Technical Problem

In general, regarding wirings in a device to which ruthenium is applied, the wirings form a stacked-layer structure. In this specification, the stacked-layer wiring is simplified into two layers, which are referred to as ruthenium located at an upper portion and ruthenium located at a bottom portion. A method has been studied in which a processing process is optimized by processing a ruthenium pattern located at an upper portion and immediately thereafter etching a ruthenium layer located at a bottom portion in a vertical direction taking the ruthenium pattern located at the upper portion as a mask.

For example, in NPL 1, a process has been proposed in which, with respect to a ruthenium pattern located at an upper portion etched in advance and ruthenium located at a bottom portion embedded via an insulating layer, ruthenium located at the bottom portion exposed to a plasma interface is etched in a vertical direction, thereby insulating adjacent elements (FIG. 1). Here, FIG. 1 illustrates wiring cross-sectional views before and after plasma processing, in which a reference sign 10 denotes a mask, a reference sign 11 denotes a ruthenium pattern located at an upper portion, a reference sign 12 denotes an insulating layer, a reference sign 13 denotes a ruthenium layer located at a bottom portion, a reference sign 14 denotes a base layer, and a reference sign 15 denotes an ion in plasma.

In addition, PTL 1 discloses a process in which a metal located at a bottom portion embedded in a dielectric is etched in a vertical direction along a pattern structure of a metal located at an upper portion (FIG. 2). Here, FIG. 2 illustrates wiring cross-sectional views before and after plasma processing, in which a reference sign 21 denotes a mask, a reference sign 22 denotes a ruthenium pattern located at an upper portion, a reference sign 23 denotes an insulating layer, a reference sign 24 denotes a base layer, and a reference sign 25 denotes a ruthenium layer located at a bottom portion.

However, in the etching process of the ruthenium layers 13 and 25 located at the bottom portion as illustrated in FIGS. 1 and 2, since the ruthenium patterns 11 and 22 located at the upper portion are also irradiated with the plasma, side etching occurs as illustrated in FIGS. 3 and 4. Further, due to the influence of etching residues in pattern grooves of the ruthenium layers 13 and 25 located at the bottom portion and a tapered shape, electrical conductivity of the ruthenium layers 13 and 25 located at the bottom portion deteriorates. A reference sign 16 in FIG. 3 and a reference sign 26 in FIG. 4 denote residues generated in the pattern grooves of the ruthenium layers 13 and 25 located at the bottom portion.

The present invention provides a technique capable of restricting side etching of ruthenium located at an upper portion, removing a residue of a ruthenium layer located at a bottom portion, and processing the ruthenium layer located at the bottom portion in a vertical direction while enhancing verticality of a pattern. Other problems and novel features thereof are shown in the description of the present description and the accompanying drawings.

### Solution to Problem

As an embodiment of the invention, a plasma processing method for performing plasma etching, by using a metal wiring pattern, on a metal film formed below the metal wiring pattern includes: a first process of forming a protective film on the metal wiring pattern by plasma generated using a first gas; a second process of etching the metal film by plasma generated using a second gas after the first process; a third process of etching the metal film after the second process by plasma generated using a third gas so that an etching shape of the metal film is a vertical shape after the second process; and a fourth process of removing, by plasma generated using a fourth gas, the protective film formed on the metal wiring pattern. The second process and the third process are repeated until an etching depth of the metal film is a predetermined depth.

### ADVANTAGEOUS EFFECTS OF INVENTION

According to the plasma processing method of the invention, in an etching process of a ruthenium layer located at a bottom portion, a sidewall of ruthenium located at an upper portion can be restricted from side etching or surface damage. In addition, it is possible to improve verticality of a pattern groove of the ruthenium layer located at the bottom portion and remove a residue. Through the above processes, it is expected that electrical conductivity of each ruthenium wiring layer processed into a pattern can be improved. As a result, a vertical ruthenium wiring layer whose pattern dimension is precisely controlled can be produced with the minimum number of processes and high throughput.

### BRIEF DESCRIPTION OF DRAWINGS

FIG. 1 is an illustrative diagram illustrating a structure of a ruthenium wiring obtained according to a method in the related art.

FIG. 2 is an illustrative diagram illustrating a structure of a ruthenium wiring obtained according to another method in the related art.

FIG. 3 is an illustrative diagram illustrating a problem of a ruthenium wiring obtained according to a method in the related art.

FIG. 4 is an illustrative diagram illustrating a problem of a structure of a ruthenium wiring obtained according to another method in the related art.

FIG. 5 is an illustrative diagram illustrating an example of an internal structure of a plasma processing apparatus (apparatus A) of the embodiment.

FIGS. 6A and 6B are illustrative diagrams illustrating an example of an internal structure of a plasma processing apparatus (apparatus B) of the embodiment.

FIG. 7 is a process flow chart in a case where the apparatus A is used and protection is provided with an altered film in the embodiment.

FIG. 8 is an illustrative diagram of the process flow in the case where the apparatus A is used and protection is provided with an altered film in the embodiment.

FIG. 9 is a process flow chart in a case where the apparatus B is used and protection is provided with an altered film in the embodiment.

FIG. 10 is an illustrative diagram of the process flow in the case where the apparatus B is used and protection is provided with an altered film in the embodiment.

FIG. 11 is a graph illustrating an etching rate of ruthenium in accordance with a flow rate ratio of oxygen and chlorine.

FIG. 12 is a table illustrating an example of a ruthenium compound predicted to be produced by ruthenium etching, and a melting point and a boiling point thereof.

FIG. 13 is a process flow chart in a case where the apparatus A is used and protection is provided with a deposition film in the embodiment.

FIG. 14 is an illustrative diagram of the process flow in the case where the apparatus A is used and protection is provided with a deposition film in the embodiment.

FIG. 15 is a process flowchart in a case where each of ruthenium layers located at upper and bottom portions is protected with an altered film in the embodiment.

FIG. 16 is an illustrative diagram of the process flow in the case where each of ruthenium layers located at upper and bottom portions is protected with an altered film in the embodiment.

FIG. 17 is an illustrative diagram of a process flow in which the embodiment is applied to the structure of the ruthenium wiring illustrated in FIG. 2.

FIG. 18 is an illustrative diagram of a process flow in which the embodiment is applied to another structure of the ruthenium wiring.

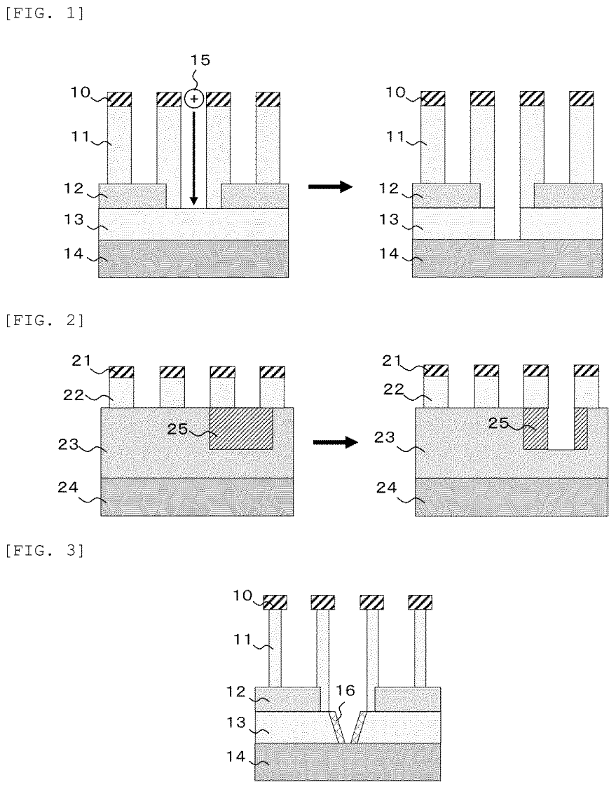

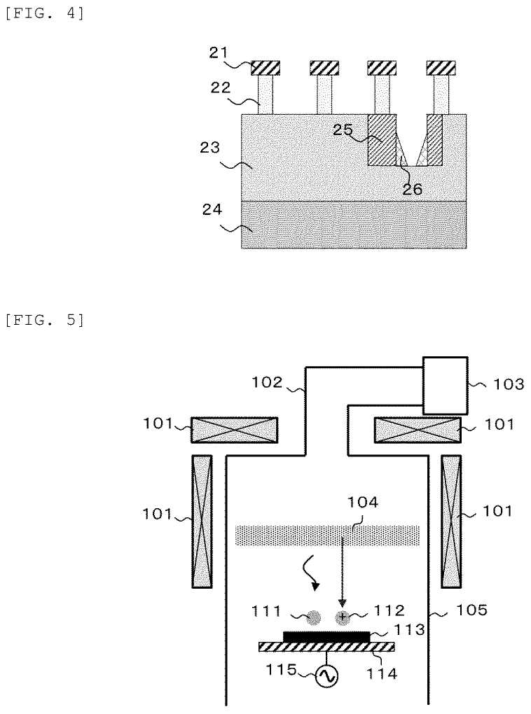

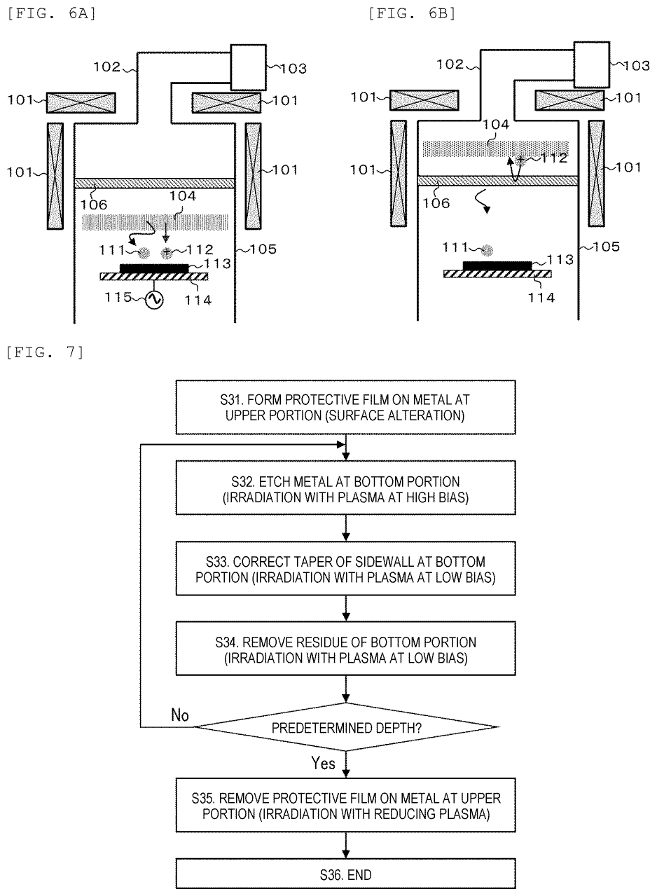

### DESCRIPTION OF EMBODIMENTS

Hereinafter, an embodiment of the invention will be described in detail with reference to the drawings. In all the drawings, components having the same functions are denoted by the same reference signs, and a repeated description thereof may be omitted. It should be noted that the drawings may be more schematically illustrated than actual aspects in order to make the description clearer, and are merely examples and do not limit the interpretation of the present disclosure.

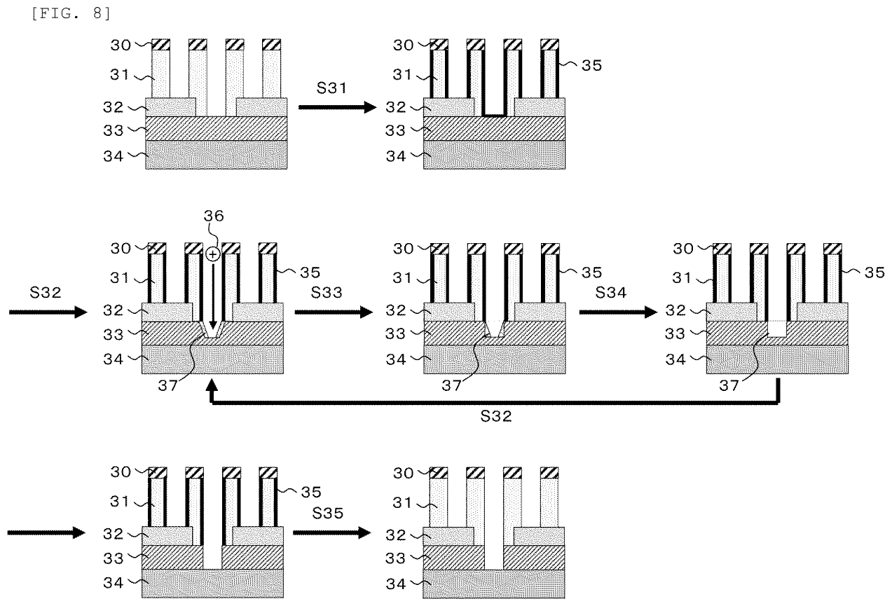

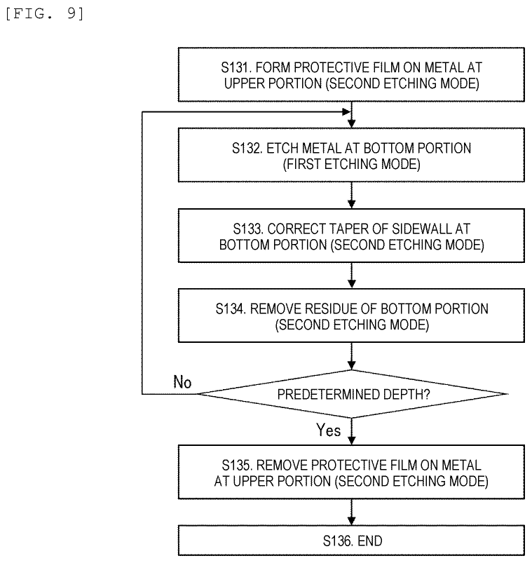

FIGS. 5, 6A and 6B are illustrative diagrams of examples of internal structures of a plasma processing apparatus according to the embodiment. Etching in the embodiment can be performed by, for example, a microwave electron cyclotron resonance plasma etcher (M-ECR) as a plasma processing apparatus.

FIG. 5 illustrates a configuration diagram of a plasma processing apparatus (hereinafter referred to as an apparatus A). The apparatus A includes an electromagnetic coil 101 for generating plasma, a microwave source 103, a circular waveguide 102, and a housing 105. Plasma 104 generated from an etchant gas contains radicals 111 and ions 112, and is applied to a ruthenium stacked-layer wiring formed on a main surface (surface) of a semiconductor wafer (also referred to as a substrate) 113 serving as a sample placed on a temperature adjustment stage 114 serving as a sample stage. A bias power supply 115 is connected to the temperature adjustment stage 114, and incident energy of the ion 112 used for etching can be adjusted by controlling an applied bias.

FIGS. 6A and 6B are illustrative diagrams of another example of an internal structure of the plasma processing apparatus according to the embodiment, in which FIG. 6A is a diagram illustrating a case where an ECR surface where plasma is formed is located on a lower side with respect to an ion shielding plate, and FIG. 6B is a diagram illustrating a case where an ECR surface where plasma is formed is located on an upper side with respect to an ion shielding plate. In FIGS. 6A and 6B, a configuration diagram of another plasma processing apparatus (hereinafter referred to as an apparatus B) is illustrated. In the apparatus B, in addition to the apparatus A in FIG. 5, an ion shielding plate 106 is installed inside the housing 105. The ion shielding plate 106 has a characteristic of allowing the radical 111 in the plasma 104 to pass and not allowing the ion 112 to pass.

When the ECR surface where the plasma 104 is formed is located on the lower side with respect to the ion shielding plate 106 (FIG. 6A), a ruthenium film formed on a main surface (surface) of the substrate 113 is irradiated with a plasma gas containing the radical 111 and the ion 112, similarly to the apparatus A in FIG. 5. On the other hand, when the ECR surface where the plasma 104 is formed is located on the upper side with respect to the ion shielding plate 106 FIG. 6B), a ruthenium film formed on a main surface (surface) of the substrate 113 is irradiated with a plasma gas containing a large amount of radicals 111 passing through the ion shielding plate 106. That is, by controlling a height of a generation region of the plasma 104, it is possible to easily in the same chamber, between a mode of performing irradiation anisotropically with the radicals 111 and the ions 112 contained in the plasma 104 (first etching mode: plasma irradiation) and a mode of performing irradiation isotropically with the radicals 111 (second etching mode: radical irradiation).

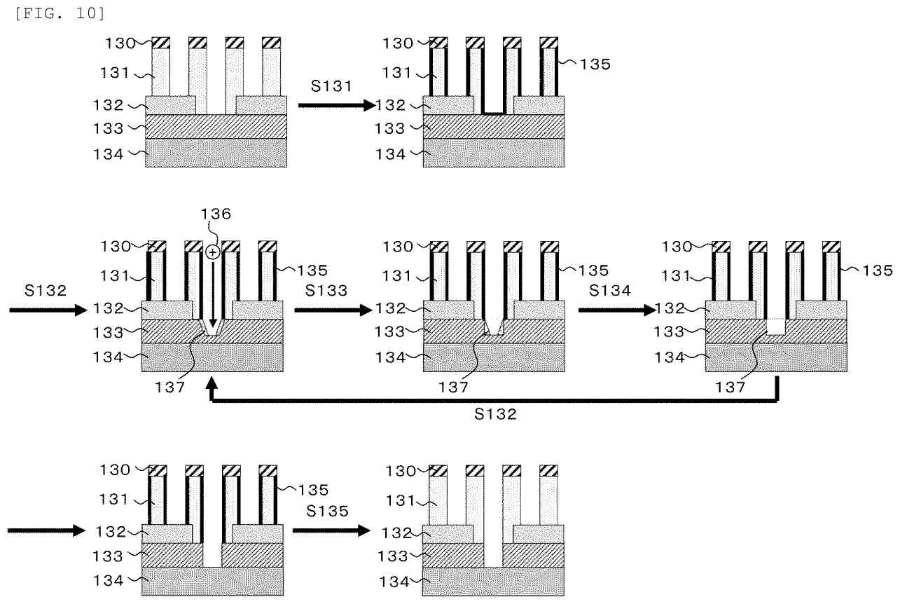

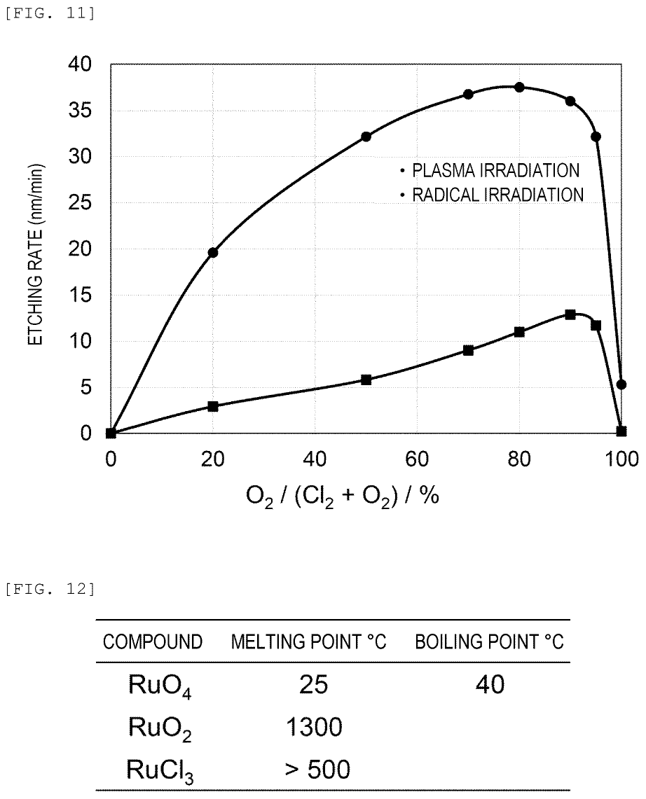

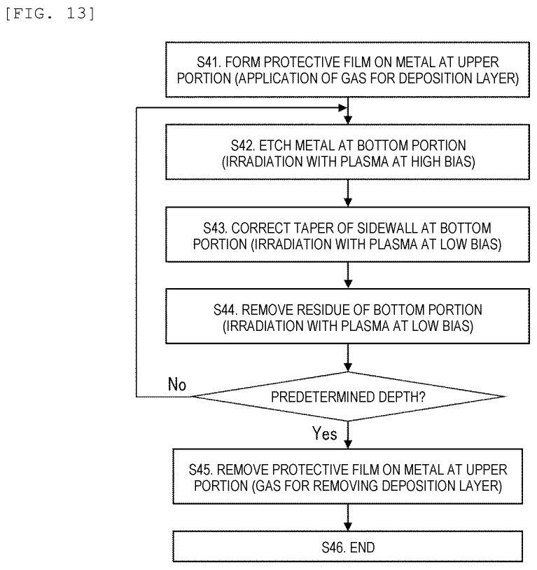

FIGS. 7, 8, 9, and 10 are flowcharts and illustrative diagrams of a method of etching a ruthenium stacked-layer wiring, and illustrate a case where a ruthenium pattern located at an upper portion is protected by a protective film of an altered film. In the case of FIGS. 7 and 8, the apparatus A in FIG. 5 is applied, and in the case of FIGS. 9 and 10, the apparatus B in FIGS. 6A and 6B is applied.

In the examples in FIGS. 7 to 10, an etching method is illustrated in which a protective film is formed by an altered film and a gas containing oxygen and chlorine is used as a gas for ruthenium etching. A stacked-layer wiring will be described as an example in which ruthenium patterns 31 and 131, which are located at an upper portion and processed into patterns in advance via masks 30 and 130, are partially connected to ruthenium layers 33 and 133 located at a bottom portion, and other regions thereof are insulated via insulating layers 32 and 132. Here, as the material of the masks 30 and 130, for example, silicon oxide, silicon nitride, or titanium nitride having low etching selectivity to the ruthenium 31 or 131 can be applied. The stacked-layer wiring is formed on base layers 34 and 134 of silicon or the like.

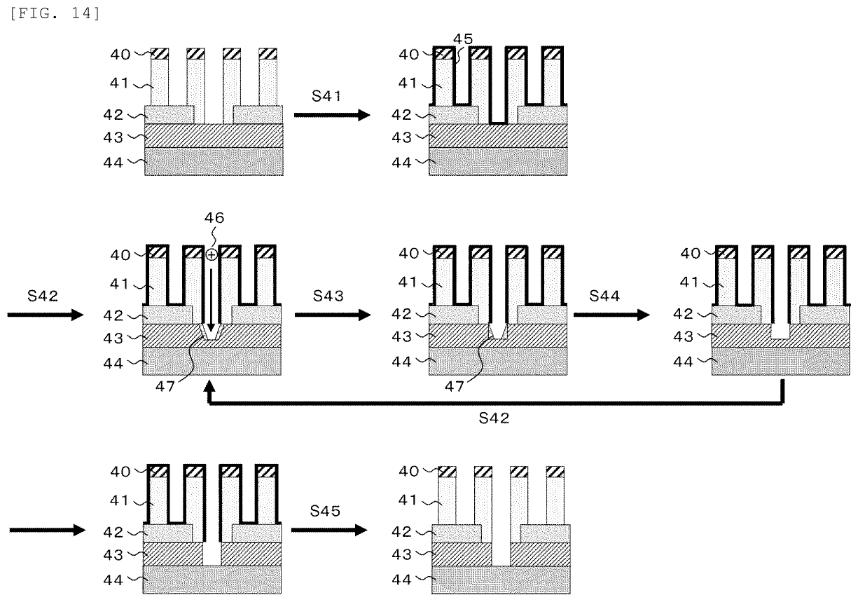

FIG. 11 is an illustrative graph illustrating dependence of an etching rate of a ruthenium film on a gas mixing ratio in a case where the apparatus B is used and the etching is performed by plasma using a gas mixture of oxygen and chlorine. A vertical axis represents the etching rate (nm/min), and a horizontal axis represents the gas mixing ratio (O₂/(Cl2+O₂)) % of the gas mixture of oxygen and chlorine. In FIG. 11, black spots indicate plasma irradiation (first etching mode), and black squares indicate radical irradiation (second etching mode). In any of the etching modes, it can be confirmed that the etching rate of the ruthenium film is maximized by adding a small amount (10% to 20%) of chlorine. In general, dry etching proceeds as the material to be etched changes to a volatile compound having a low boiling point by a chemical reaction, and when the material is changed to a nonvolatile product, the etching stops.

FIG. 12 illustrates an example of a ruthenium compound produced by a chemical reaction between a plasma gas containing oxygen and chlorine and ruthenium, and its melting point (°C) and boiling point (C). A ruthenium dioxide (RuO₂) has a melting point of 1300° C. or higher, is nonvolatile, and is expected to be formed as an intermediate of an etching reaction. RuO₄ formed by further oxidation has volatility and a low boiling point. That is, a rate of oxidation reaction of ruthenium is increased by chlorine added in a small amount, and a volatile ruthenium compound such as RuO₄ and a ruthenium chloride (RuClₓO_{y}) is formed. As a result, the etching is expected to proceed.

On the other hand, it can be confirmed from FIG. 11 that when a flow rate ratio of chlorine increases exceeding 20%, the etching rate of ruthenium decreases, and when the flow rate ratio of chlorine gas is close to 100%, the etching hardly proceeds. This is because when a ruthenium surface is irradiated with chlorine plasma, a nonvolatile ruthenium chloride (RuCl₃) having a melting point of 500 °C or higher is generated. That is, it is conceivable that when the ruthenium surface is irradiated with a plasma gas containing a large amount of chlorine, a nonvolatile film is formed on the ruthenium surface and the etching reaction of ruthenium is inhibited. In the examples in FIGS. 7 to 10, the nonvolatile ruthenium film is used as a sidewall protective film for pattern etching.

First, an example of a pattern etching method in which the device A is used and the ruthenium pattern 31 located at an upper portion is protected by an altered film 35 will be described (see FIGS. 5, 7, and 8). In FIG. 8, drawings pointed by arrows indicated by S31, S32, S33, S34, and S35 correspond to cross-sectional views after respective processes (S31, S32, S33, S34, and S35) in FIG. 7.

In a wiring structure in which the ruthenium pattern 31 located at the upper portion is etched in advance, in a first process (S31: protective film formation), a sidewall of the ruthenium pattern 31 located at the upper portion is irradiated with a plasma gas containing a large amount of chlorine, thereby protecting the ruthenium pattern 31 with the altered film 35 derived from ruthenium chloride. At this time, both ions and radicals are contained in the plasma, and the altered film 35 is formed on the entire ruthenium surface in contact. Accordingly, the altered film 35 is formed not only on the sidewall of the ruthenium pattern 31 located at the upper portion but also on a part exposed to a plasma interface at the ruthenium layer 33 located at a bottom portion. In this process, when plasma generated from a gas containing sulfur (such as SO₂) instead of chlorine is used for irradiation, a ruthenium sulfide is formed as the altered film 35, and when plasma generated from a gas containing nitrogen (such as N₂) is used for irradiation, a ruthenium nitride is formed as the altered film 35. Accordingly, these gases may be applied.

In a second process (S32: vertical processing of the ruthenium layer located at the bottom portion), the ruthenium layer 33 located at the bottom portion is processed in a vertical direction by ions 36. A bias of radio frequency power applied from the bias power supply 115 to the substrate 113 via the temperature adjustment stage 114 is set to be large enough to allow the ions to pass through the altered film 35 on the surface of the ruthenium layer 33 located at the bottom portion, and a gas mixture having a flow rate ratio of oxygen and chlorine at around 80% to 20% is used. In this process, in order to etch the ruthenium pattern 31 in the vertical direction, it is desirable to irradiate the substrate 113 with a plasma gas after applying a high bias as a power value of the radio frequency power supplied to the temperature adjustment stage 114. Further, the power value of the radio frequency power applied to the substrate 113 via the temperature adjustment stage 114 is set to a power value necessary for sputtering and removing the altered film 35 formed on the surface of the ruthenium layer 33 located at the bottom portion.

In a third process (S33: taper angle adjustment), a plasma gas generated from a gas containing oxygen and chlorine is used, and a pattern groove of the ruthenium layer 33 located at the bottom portion is etched in a horizontal direction to adjust a pattern shape to be vertical. Since the etching in the horizontal direction is caused by a chemical reaction by radicals, it is desirable to set an applied bias in this process to zero or a low bias. In order to control a rate of the chemical reaction by radicals, a substrate temperature may be adjusted by the temperature adjustment stage 114. In this process, etching conditions are adjusted so that a dimension of the pattern groove is a desired dimension.

In a fourth process (S34: residue removal), in order to remove a residue 37 in the pattern groove of the ruthenium layer 33 located at the bottom portion, a plasma gas generated from a gas containing oxygen and chlorine is used for irradiation. Since it also proceeds by a chemical reaction by radicals in the fourth process, it is desirable to set an applied bias to zero or a low bias. Since a main component of the residue 37 is expected to be ruthenium, it is conceivable to remove the residue 37 by etching by radicals derived from oxygen and chlorine. In order to control a rate of the chemical reaction by radicals, a substrate temperature may be adjusted by the temperature adjustment stage 114.

Thereafter, the second to fourth processes are repeated until the ruthenium layer 33 located at the bottom portion has a predetermined pattern groove depth. When the ruthenium layer 33 located at the bottom portion has the predetermined pattern groove depth after the fourth process (S34), the process proceeds to a fifth process (S35).

In the fifth process (S35: reduction removal of altered film), in order to return the surface of the ruthenium pattern 31 located at the upper portion to the metal ruthenium by reducing the altered film 35, a reducing gas or a plasma gas derived from a reducing gas is used for irradiation. For example, when a ruthenium chloride is irradiated with hydrogen radicals (H+) contained in plasma generated from a gas containing a hydrogen gas, a reaction of RuCl₃+3H*→Ru+3HCl occurs, and thus the altered film 35 on the pattern surface can be reduced to the metal ruthenium. That is, the fifth process (S35) is a process of reducing a ruthenium compound to metal ruthenium after the fourth process (S34). When the fifth process (S35) is completed, the pattern etching of the ruthenium layer 33 located at the bottom portion is completed (S36).

A superior characteristic of the embodiment is the first process (S31) of forming a protective film of the altered film 35 on the ruthenium pattern 31 located at the upper portion of a stacked two-layered ruthenium wiring. When the ruthenium layer 33 located at the bottom portion is subjected to vertical processing without applying this process, both the ruthenium pattern 31 located at the upper portion and the ruthenium layer 33 located at the bottom portion are exposed to plasma. As a result, there is a concern that the sidewall of the ruthenium pattern 31 located at the upper portion is etched, resulting in an unintended pattern shape. When this process is applied, the sidewall of the ruthenium pattern 31 located at the upper portion is protected by the altered film 35, and is not exposed to the etching gas. Accordingly, the etching of the sidewall of the ruthenium pattern 31 located at the upper portion can be restricted. Although the altered film 35 is also formed on the surface of the ruthenium layer 33 located at the bottom portion, since the ruthenium layer 33 located at the bottom portion is etched in the vertical direction in the second process (S32), the altered film 35 can be removed by physical sputtering by impact of ions. Accordingly, the sidewall of the ruthenium pattern 31 located at the upper portion is protected, and the ruthenium layer 33 located at the bottom portion can be Selectively subjected to vertical processing.

Since the processes of the embodiment includes a process (S31) of isotropically forming the altered film 35 on a pattern surface, a pattern dimension adjusting process (S33), residue removal (S34), and a pattern forming process (S32) by anisotropic etching, when the apparatus B is used, these processes can be executed in the same chamber. Hereinafter, a process in which the apparatus B is used and the ruthenium pattern 131 located at an upper portion is protected by an altered film 135 will be described (see FIGS. 6, 9, and 10). In FIG. 10, drawings pointed by arrows indicated by S131, S132, S133, S134, and S135 correspond to cross-sectional views after respective processes (S131, S132, S133, S134, S135) in FIG. 9.

In the apparatus B, it is characterized that the ruthenium layer 133 located at a bottom portion can be processed while complementarily using the first etching mode and the second etching mode. Hereinafter, a process in which a gas containing oxygen and chlorine is used will be described. When applying the first etching mode and the second etching mode, an applied bias and a substrate temperature may be adjusted in order to optimize a pattern shape.

In a process of forming the altered film 135 in a first process (S131: protective film formation), a gas containing chlorine as a main component is used, and plasma is generated in the second etching mode, so that plasma containing a large amount of chlorine radicals is used for isotropic irradiation. By applying this method, surface damage caused by the ion collision can be restricted and the altered film 135 formed of ruthenium chloride can be formed homogeneously, as compared with the corresponding process (S31) of the apparatus A that performs irradiation with both ions and radicals.

In a second process (S132), the first etching mode is applied, and the ruthenium layer 133 located at a bottom portion is etched in the same manner as in the corresponding process (S32) in which the apparatus A is used.

In a third process (S133: taper angle adjustment), plasma is generated in the second etching mode, and a taper angle of a pattern groove of the ruthenium layer 133 located at a bottom portion is adjusted by isotropic etching.

In a fourth process (S134: residue removal), plasma is generated in the second etching mode, and a residue 137 of the pattern groove of the ruthenium layer 133 located at the bottom portion is removed by isotropic etching.

In a fifth process (S135: reduction removal of altered film), plasma is generated in the second etching mode, and the altered film on the surface of the ruthenium pattern 131 located at the upper portion is reduced isotropically.

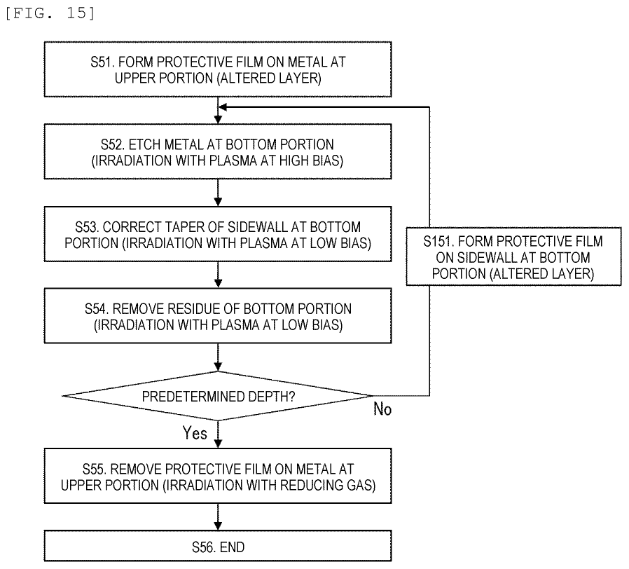

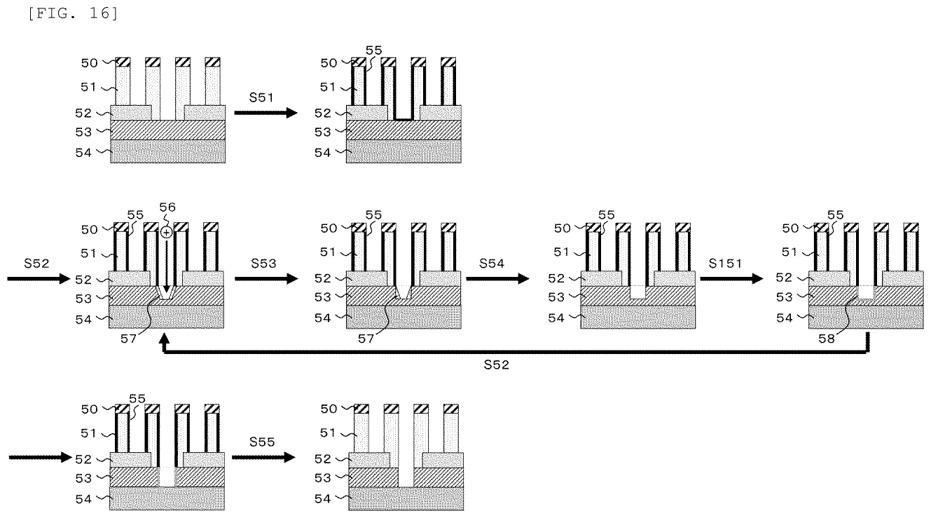

Next, a method in a case where the apparatus A is used and a ruthenium pattern 41 located at an upper portion is protected by a deposition film 45 will be described (see FIGS. 13 and 14). In FIG. 14, drawings pointed by arrows indicated by S41, S42, S43, S44, and S45 correspond to cross-sectional views after respective processes (S41, S42, S43, S44, and S45) in FIG. 13.

In a first process (S41), a precursor gas of the deposition film 45 is applied in order to protect the ruthenium pattern 41 located at the upper portion with the deposition film 45. For example, when a carbon-based precursor gas such as carbon dioxide or methane is applied, an organic deposition film is formed at the interface. When a silane-based or halogenated-tungsten-based precursor gas is applied, an inorganic deposition film derived from silicon or tungsten is formed. A flow rate, a pressure, an application duration, and a substrate temperature for the precursor gas are determined based on data acquired in advance, and the deposition film 45 is formed so as to have an appropriate film thickness.

In a second process (S42), a third process (S43), and a fourth process (S44), the processing is performed in the same process as the corresponding process flow (S32, S33, S34) illustrated in FIG. 7.

In a fifth process (S45), the deposition film 45 remaining on the ruthenium pattern 41 is removed by plasma processing. When the deposition film 45 is organic, for example, the deposition film 45 can be removed by performing ashing with a plasma gas containing oxygen. When the deposition film 45 is silicon-based or metal, the deposition film 45 is removed by being irradiated with a plasma gas that generates a volatile silicon compound or a volatile metal compound (for example, a gas containing a halogen-based gas as a main component).

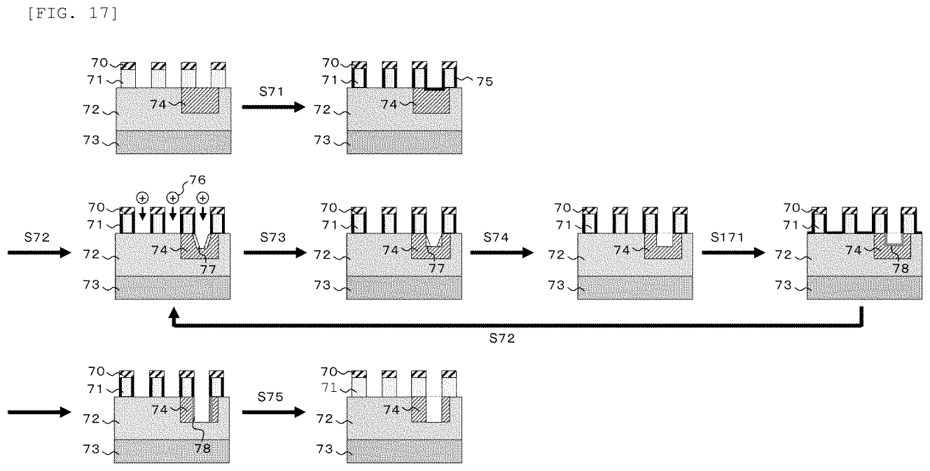

Next, a plasma processing method for more accurately controlling a pattern shape by adding a process (S151) of forming a protective film in a pattern groove of a ruthenium layer 53 located at a bottom portion will be described (see FIGS. 15 and 16). In FIG. 16, drawings pointed by arrows indicated by S51, S52, S53, S54, S151, and S55 correspond to cross-sectional views after respective processes (S51, S52, S53, S54, S151, S55) in FIG. 15. The processes (S51, S52, S53, S54, S55, S56) shown in FIGS. 15 and 16 correspond to the processes (S31, S32, S33, S34, S35, S36) shown in FIGS. 7 and 8.

In the plasma processing method, etching of the ruthenium layer 53 located at a bottom portion in the second process (S52) is temporarily stopped before bowing or surface roughness is formed. In the third process (S53), a taper angle in the pattern groove of the ruthenium layer 53 located at the bottom portion is corrected, and in the fourth process (S54), a residue 57 is removed.

Thereafter, the process returns to the second process (S52), and the sixth process (S151) of forming a protective film 58 in the pattern groove of the ruthenium layer 53 located at the bottom portion is added before the etching of the ruthenium layer 53 located at the bottom portion is restarted. In this process, in a region of the pattern groove of the ruthenium layer 53 located at the bottom portion that is in contact with the plasma, the protective film 58 is formed by the same method (halogenation, sulfuration, or nitridization) as a protective film 55 of a ruthenium pattern located at an upper portion.

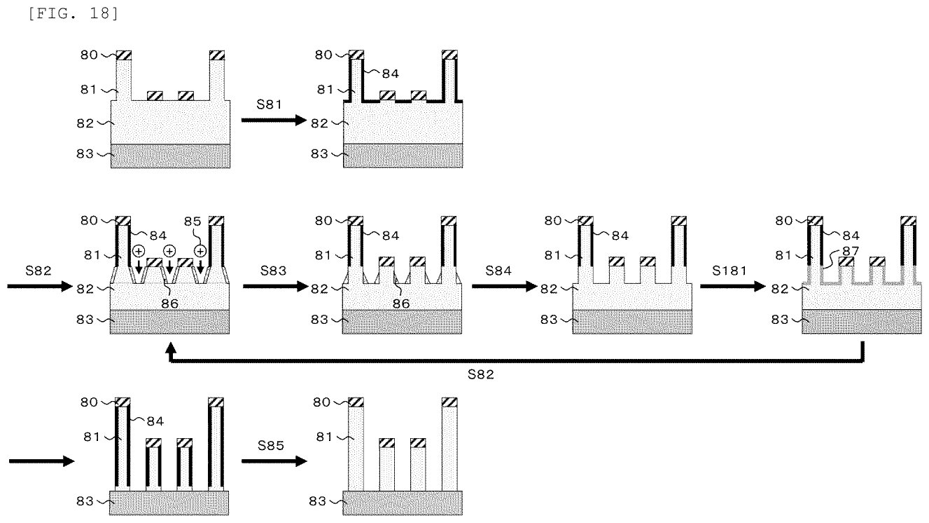

As described above, by repeatedly performing the second process (S52), the third process (S53), the fourth process (S54), and the sixth process (S151), the plasma processing can be performed while restricting sidewall etching of the ruthenium layer 53 located at the bottom portion. In the fifth process (S55), the protective film 55 of a ruthenium pattern 51 located at the upper portion and the protective film 58 formed on the ruthenium layer 53 located at the bottom portion are reduced to metal ruthenium by the same method as in S35 of FIG. 7. which the embodiment is applied to a plasma processing process of vertically processing a ruthenium layer 74, which is located at a bottom portion and is embedded in an insulating layer 72, along a sidewall of a pattern groove of a ruthenium layer 71 located at an upper portion in a structure of the ruthenium wiring illustrated in FIG. 2. Processes (S71, S72, S73, S74, S171, S75) in FIG. 17 correspond to processes (S51, S52, S53, S54, S151, S55) in FIGS. 15 and 16, and any process is performed in the same manner as the corresponding process in FIGS. 15 and 16.

FIG. 18 is an illustrative diagram of a process flow in which the embodiment is applied to another structure of the ruthenium wiring. In the structure of the ruthenium wiring in FIG. 18, a ruthenium pattern 81 located at an upper portion and a ruthenium layer 82 located at a bottom portion are cut out from the same bulk ruthenium, and are both etched in a vertical direction via a mask 80 to form ruthenium patterns having different heights, which is intended. Processes (S81, S82, S83, S84, S181, S85) in FIG. 18 correspond to processes (S51, S52, S53, S54, S151, S55) in FIGS. 15 and 16, and any process is performed in the same manner as the corresponding process in FIGS. 15 and 16.

Although a case where a ruthenium pattern is etched has been described as an example in the embodiment, for a metal material such as molybdenum, the plasma etching is also possible, and a pattern can be processed by performing sidewall protection of the pattern using the same method.

Although a specific description has been made based on the embodiment, the invention is not limited to the embodiment, and it is needless to say that various modifications can be made without departing from the gist of the invention. For example, the embodiment described above has been described in detail to facilitate understanding of the invention, and the invention is not necessarily limited to those including all the configurations described above. A part of a configuration of each embodiment may be added to, deleted from, or replaced with another configuration.

### REFERENCE SIGNS LIST

10: mask
11: ruthenium pattern located at upper portion
12: insulating layer
13: ruthenium layer located at bottom portion
14: base layer
15: ion
16: residue
21: Mask
22: ruthenium pattern located at upper portion
23: insulating layer
24: base layer
25: ruthenium layer located at bottom portion
26: residue
101: electromagnetic coil
102: circular waveguide
103: microwave source
104: plasma
105: housing
106: ion shielding plate
111: radical
112: ion
113: substrate
114: temperature adjustment stage
115: bias power supply
30: mask
31: ruthenium pattern located at upper portion
32: insulating layer
33: ruthenium layer located at bottom portion
34: base layer
35: altered film
36: ion
130: Mask
131: ruthenium pattern located at upper portion
132: insulating layer
133: ruthenium layer located at bottom portion
134: base layer
135: altered film
136: ion
137: residue
40: mask
41: ruthenium pattern located at upper portion
42: insulating layer
43: ruthenium layer located at bottom portion
44: base layer
45: deposition film
46: ion
47: residue
50: mask
51: ruthenium pattern located at upper portion
52: insulating layer
53: ruthenium layer located at bottom portion
54: base layer
55: altered film
56: ion
57: residue
58: altered film
70: Mask
71: ruthenium pattern located at upper portion
72: insulating layer
73: base layer
74: ruthenium layer located at bottom portion
75: altered film
76: ion
77: residue
78: altered film
80: mask
81: ruthenium pattern located at upper portion
82: ruthenium layer located at bottom portion
83: base layer
84: altered film
85: ion
86: residue
87: altered film

1. A plasma processing method for performing plasma etching, by using a metal wiring pattern, on a metal film formed below the metal wiring pattern, the method comprising:
a first process of forming a protective film on the metal wiring pattern by plasma generated using a first gas;
a second process of etching the metal film by plasma generated using a second gas after the first process;
a third process of etching the metal film after the second process by plasma generated using a third gas such that an etching shape of the metal film is a vertical shape after the second process; and
a fourth process of removing, by plasma generated using a fourth gas, the protective film formed on the metal wiring pattern, wherein
the second process and the third process are repeated until an etching depth of the metal film is a predetermined depth.

2. The plasma processing method according to claim 1, wherein
the metal film is a ruthenium film or a molybdenum film.

3. The plasma processing method according to claim 1, wherein
the protective film is an altered film, and
the altered film is formed by plasma generated using a gas generating a nonvolatile compound containing a metal element.

4. The plasma processing method according to claim 3, wherein
the nonvolatile compound is a nitride compound, a sulfurized compound, or a halogenated compound.

5. The plasma processing method according to claim 1, wherein
the protective film is formed by plasma generated using a precursor gas containing a carbon element, a silicon element, or a metal element.

6. The plasma processing method according to claim 1, wherein
the metal film after the second process is etched using radicals generated by the plasma in the third process.

7. The plasma processing method according to claim 1, further comprising:
a process of removing a residue on the metal film.

8. The plasma processing method according to claim 1, wherein
the protective film is an altered film, and
in the fourth process, the altered film is removed by a reduction treatment.

9. The plasma processing method according to claim 1, wherein
the metal film is a ruthenium film, and
the second gas and the third gas are a gas mixture of an oxygen gas and a halogen gas.

10. The plasma processing method according to claim 1, wherein
a part of the metal wiring pattern is connected to the metal film.

11. The plasma processing method according to claim 1, wherein
the metal film is embedded in a groove formed below the metal wiring pattern.

12. The plasma processing method according to claim 1, wherein
all of the metal wiring patterns are connected to the metal film, and
in the second process, the metal wiring pattern and the metal film are etched by the plasma generated using the second gas.
